(19) United States
(12) Patent Application Publication
(10) Pub. No.: US 2025/0210406 A1
(43) Pub. Date: Jun. 26, 2025

(54) Workpiece Support For Backside Processing Using Edge Grip

(71) Applicant: Applied Materials, Inc., Santa Clara, CA (US)

(72) Inventor: Roger B. Fish, Bedford, MA (US)

(21) Appl. No.: 18/392,246

(22) Filed: Dec. 21, 2023

(51) Int. Cl. H01L 21/687

(52) U.S. Cl. CPC H01L 21/68721; H01L 21/68785

(57) ABSTRACT

A workpiece support system is disclosed. This support system allows the back surface of a workpiece to be exposed to an incoming ion beam while the front surface of the workpiece remains untouched. The workpiece support system includes pivotable latches that have an open position and a closed position. In the closed position, the pivotable latches contact only the edge exclusion zone of the workpiece. This reduces the possibility of damage to the front surface of the workpiece. Further, the workpiece support system may include a gimbal allowing multiple degrees of rotational freedom.

### FIELD

Embodiments of the present disclosure relate to a workpiece support that allows processing of the backside without contacting the front surface of the workpiece.

### BACKGROUND

The fabrication of semiconductor devices continues to become more complex. Currently, there are scenarios in which it may be desirable to process both surfaces of a workpiece, such as a silicon, silicon carbide or GaN wafer. For example, to create certain structures, it may be beneficial to perform an ion implantation process on both surfaces of a workpiece. Implantation to the backside of semiconductor device wafers has become common in power device fabrication applications. In this scenario, dopants are implanted to the underside of a chip to improve electrical performance. One such application is adding a Field Stop region to an IGBT device. A second type of backside processing is ion implantation to relieve or control wafer stress and physical deformation. Selective ion implantation can be used to reduce wafer curvature, which makes lithography more difficult.

Typically when both surfaces of the workpiece are to be processed, this may be achieved by processing the front surface first.

However, in certain embodiments, the processing of the front surface may include the formation of three-dimensional structures, such as finFETs. Once these three-dimensional structures are created, placing the front surface against an electrostatic chuck risks damaging these structures.

Therefore, it would be beneficial if there were a system that allowed the backside of a workpiece to be processed without having to contact the processed front surface. Further, it would be advantageous if this system allowed rotation and tilt of the workpiece, as is traditionally performed using an electrostatic chuck.

### SUMMARY

A workpiece support system is disclosed. This support system allows the back surface of a workpiece to be exposed to an incoming ion beam while the front surface of the workpiece remains untouched. The workpiece support system includes pivotable latches that have an open position and a closed position. In the closed position, the pivotable latches contact only the edge exclusion zone of the workpiece. This reduces the possibility of damage to the front surface of the workpiece. Further, the workpiece support system may include a gimbal allowing multiple degrees of rotational freedom.

According to one embodiment, a workpiece support system is disclosed. The workpiece support system comprises a workpiece bracket, rotatably coupled to a support arm; a workpiece holder rotatably mounted to the workpiece bracket; wherein the workpiece holder comprises: a workpiece holder ring; and a plurality of workpiece clamps disposed along a diameter of the workpiece holder ring, the plurality of workpiece clamps each comprising a seat on which a bottom surface of a workpiece rests, and a pivotable latch, operable to clamp a front surface of the workpiece when in a closed position and unclamp the workpiece when in an open position. In some embodiments, the workpiece holder ring is rotatable about a tilt axis. In certain embodiments, when in the closed position, the workpiece clamps retain the workpiece when the workpiece holder is rotated at any tilt angle. In some embodiments, the workpiece bracket is rotatable about a twist axis. In some embodiments, when in the closed position, the pivotable latch covers only an edge exclusion zone of the workpiece. In some embodiments, each of the plurality of workpiece clamps comprises: the seat attached to an inner diameter of the workpiece holder ring, having a body and a top ledge, wherein the body has a hollow conduit passing therethrough, and the top ledge supports the bottom surface of the workpiece. In certain embodiments, each of the plurality of workpiece clamps comprises a shaft passing through the hollow conduit, rigidly attached to the pivotable latch at a distal end and rigidly affixed to a lever at a proximal end. In certain embodiments, a clamp actuator is in communication with a clamping linkage, and each of the levers is attached to the clamping linkage, such that actuation of the clamp actuator causes all of the shafts to rotate between the open position and the closed position. In certain embodiments, a return spring is in communication with the clamping linkage, and the return spring biases the clamping linkage to either the open position or the closed position and actuation of the clamp actuator rotates the shafts to the other of the open position and the closed position. In some embodiments, a plurality of clamp actuators are each in communication with the lever of a respective workpiece clamp, such that actuation of the plurality of clamp actuators causes all of the shafts to rotate between the open position and the closed position. In certain embodiments, a plurality of return springs are each in communication with the lever of a respective workpiece clamp, and the return spring biases the lever to either the open position or the closed position and actuation of a respective clamp actuator rotates the shaft to the other of the open position and the closed position. In some embodiments, the workpiece holder ring comprises a cutout along a portion of a front surface to allow insertion and removal of a robotic arm.

According to another embodiment, a workpiece support system is disclosed. The workpiece support system comprises a workpiece bracket; a workpiece holder rotatably mounted to the workpiece bracket; wherein the workpiece holder comprises: a workpiece holder ring; and a plurality of workpiece clamps disposed along a diameter of the workpiece holder ring; the plurality of workpiece clamps each comprising: a seat attached to an inner diameter of the workpiece holder ring, having a body and a top ledge, wherein the body has a hollow conduit passing therethrough, and the top ledge supports a bottom surface of a workpiece; and a shaft passing through the hollow conduit, rigidly attached to a pivotable latch at a distal end and rigidly affixed to a lever at a proximal end. In some embodiments, when in a closed position, the pivotable latch covers only an edge exclusion zone of the workpiece. In some embodiments, a clamp actuator is in communication with a clamping linkage, and each of the levers is attached to the clamping linkage, such that actuation of the clamp actuator causes all of the shafts to rotate between an open position and a closed position. In certain embodiments, a return spring is in communication with the clamping linkage, and the return spring biases the clamping linkage to either the open position or the closed position and actuation of the clamp actuator rotates the shafts to the other of the open position and the closed position. In some embodiments, the workpiece support system comprises a protective cover, such that the clamping linkage is disposed between the protective cover and an underside of the workpiece holder ring. In some embodiments, the workpiece bracket and the workpiece holder form a gimbal having two degrees of rotational freedom. In some embodiments, a plurality of clamp actuators are each in communication with the lever of a respective workpiece clamp, such that actuation of the plurality of clamp actuators causes all of the shafts to rotate between an open position and a closed position. In certain embodiments, a plurality of return springs are each in communication with the lever of a respective workpiece clamp, wherein the return spring biases the lever to either the open position or the closed position and actuation of a respective clamp actuator rotates the shaft to the other of the open position and the closed position.

### BRIEF DESCRIPTION OF THE FIGURES

For a better understanding of the present disclosure, reference is made to the accompanying drawings, which are incorporated herein by reference and in which:

FIG. 1 shows the workpiece support system according to one embodiment;

FIGS. 2A-2B show the workpiece support system of FIG. 1 at different tilt and twist angles;

FIGS. 3A-3B show a top and bottom view, respectively, of the workpiece holder;

FIGS. 4A-4B show the workpiece clamp in the open position;

FIGS. 5A-5B show the workpiece clamp in the closed or latched position;

FIGS. 6A-6B show the workpiece and the workpiece clamp in the open and closed positions, respectively; and

FIGS. 7A-7D show the sequence of operations to load a workpiece onto the workpiece support system.

### DETAILED DESCRIPTION

As described above, in certain systems, it may be desirable to process the backside of a workpiece without contacting the useable region of the front surface.

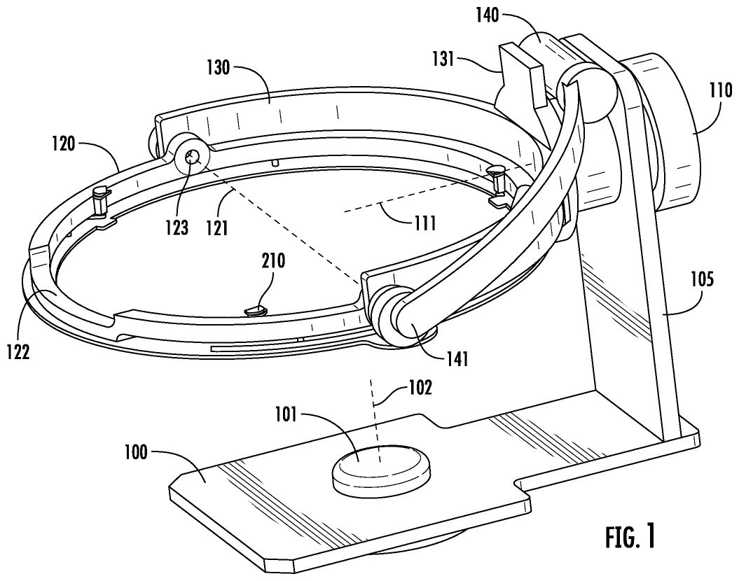

FIG. 1 shows a workpiece support system that achieves this objective. The workpiece support includes a base 100, which includes a locking mechanism that rests on a rotatable shaft 101. The base 100 may removably couple onto the rotatable shaft 101, such that rotation of the rotatable shaft 101 about axis 102 causes corresponding rotation of the base 100. Additionally, linear translation of the rotatable shaft 101 in the height or Z direction (i.e. parallel to axis 102) causes corresponding linear movement of the base 100. The base 100 is in contact with a support arm 105. The distance from the center of the locking mechanism to the support arm 105 may be greater than the radius of the workpiece to be supported. The base 100 and the support arm 105 may be constructed from aluminum.

The support arm 105 is used to create separation in the height or Z direction between the base 100 and the workpiece holder 120, when it is in the operational position, as described in more detail below.

Attached to the support arm 105 is a twist motor 110. The twist motor 110 may include a shaft that passes through the support arm 105 and is attached to the workpiece bracket 130. In other embodiments, the twist motor 110 may be in communication with the workpiece bracket t 130 through one or more gears. In certain embodiments, the twist motor 110 is located on the opposite side of the support arm 105 from the workpiece bracket 130. This may serve to protect the twist motor 110 from the ion beam while the workpiece is being processed.

Due to its connection to the twist motor 110, the workpiece bracket 130 is able to rotate about twist axis 111. In some embodiments, the twist motor 110 is direct drive, such as a stepper motor. In this instance, the twist motor 110 may readily determine the amount of twist that the workpiece bracket 130 is experiencing. In other embodiments, an encoder may be used to determine the amount of twist that the workpiece bracket 130 is experiencing. In other embodiments, there may be a linkage between the twist motor 110 and the workpiece bracket 130, such as one or more gears. If a linkage is used, an encoder or stepper motor may be used to monitor the amount of twist.

The workpiece bracket 130 may be C-shaped. In certain embodiments, the workpiece bracket 130 may have a semicircular shape, wherein the inner diameter of the semicircle is larger than the outer diameter of the workpiece holder 120. The workpiece bracket 130 may include two rotational joints, which are aligned with connection points 123 on the workpiece holder 120. These rotational joints allow rotation of the workpiece holder 120 about tilt axis 121, which is the primary orientation axis for positioning the workpiece for loading/unloading and processing of the front and back sides of the workpiece. During processing, the workpiece holder 120 may be set at any tilt angle by rotation about tilt axis 121. The rotational joints in the workpiece bracket 130 and the connection points 123 in workpiece holder 120 are positioned such that a tilt axis 121 passes through all of the connection points and may also be coincident with a diameter of the workpiece holder 120.

The workpiece holder 120 has a round hollow shape, slightly larger than the diameter of the workpiece which it is intended to hold. As noted above, the workpiece holder 120 has two connection points 123 that are diametrically opposed from one another. Each connection point 123 is aligned with a corresponding rotational joint in the workpiece bracket 130. While this embodiment uses two rotational joints, in other embodiments a single rotational joint may be used, given sufficient mechanical strength.

A tilt motor 140 may be disposed on the support arm 105 or on the workpiece bracket 130. In one particular embodiment, the tilt motor 140 is located on the workpiece bracket 130 and a flange 131 is formed on the workpiece bracket 130 to protect the tilt motor 140 from the incoming ion beam. The tilt motor 140 may be a stepper motor. In other embodiments, the tilt motor 140 may include an encoder to monitor the amount of tilt that the workpiece holder 120 experiences.

Further, in some embodiments, the tilt motor 140 is in communication with a tilt motor coupler 141. The tilt motor coupler 141 is located on the workpiece bracket 130 near one of the rotational joints. The tilt motor coupler 141 couples the rotation from the tilt motor 140 to one of the rotational joints. One embodiment uses a wire loop in a push-pull arrangement where rotation of the tilt motor 140 is coupled to a pulley, which serves as the tilt motor coupler 141. Of course, the tilt motor coupler 141 may be implemented in other ways. In another embodiment, a tilt motor coupler 141 may not be used. Rather, the tilt motor 140 may be positioned at the side of the workpiece bracket 130 (in the position shown for the tilt motor coupler 141).

In one embodiment, the connection points are holes in the sidewalls of the workpiece holder 120. A shaft is attached to the rotational joint and is inserted through a connection point on the workpiece holder 120. These shafts pivotably support the workpiece holder 120.

In some embodiments, one of the shafts is in communication with a tilt motor coupler 141. In one embodiment, this shaft may have teeth and is meshed with a similar configured receptacle on the workpiece holder 120. In some embodiments, the shaft may be in communication with a pulley which rotates the shaft. Thus, rotation by the tilt motor 140 causes a corresponding rotation of the workpiece holder 120.

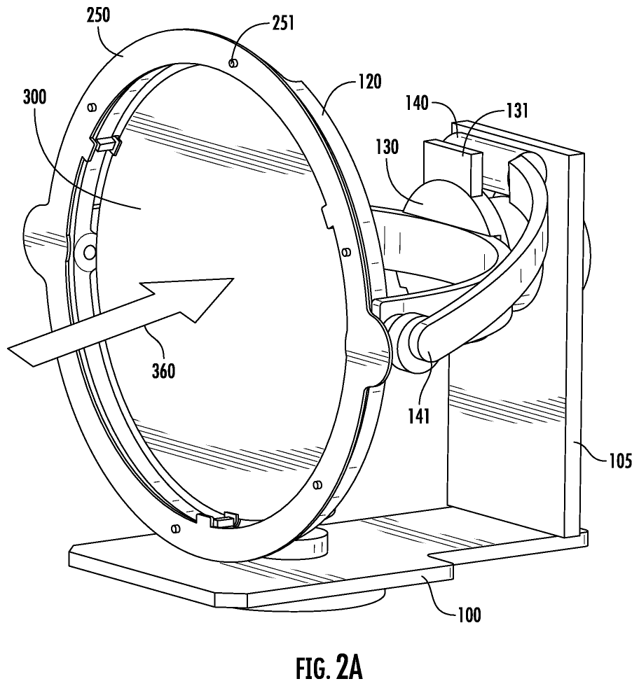

FIG. 2A shows the workpiece support system of FIG. 1 where the tilt motor 140 has caused a 90° rotation of the workpiece holder 120. Note that in this embodiment, the backside of the workpiece 300 may be exposed to an incoming ion beam 360. FIG. 2B shows the workpiece support system of FIG. 1 where the tilt motor 140 has caused a 90° rotation of the workpiece holder 120 about tilt axis 121 and the twist motor 110 has caused a rotation of the workpiece bracket 130 about twist axis 111.

Thus, the workpiece bracket 130 and the workpiece holder 120 make up a two-degree of freedom set of gimbals. The workpiece bracket 130 is rotatable about the twist axis 111. The workpiece holder 120 is mounted to the workpiece bracket 130 and is rotatable about the tilt axis 121, which is orthogonal to the twist axis 111. Further, when mounted on the rotatable shaft 101, the workpiece support system provides three degrees of rotational freedom, as well as linear translation in one direction. Thus, the workpiece support system provides the same configurability as a traditional platen. Of course, other structures may be used to create the two degree of freedom gimbal assembly.

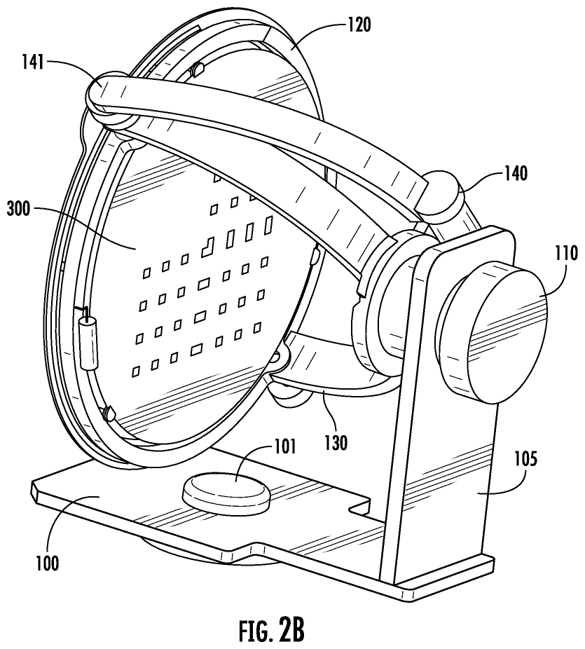

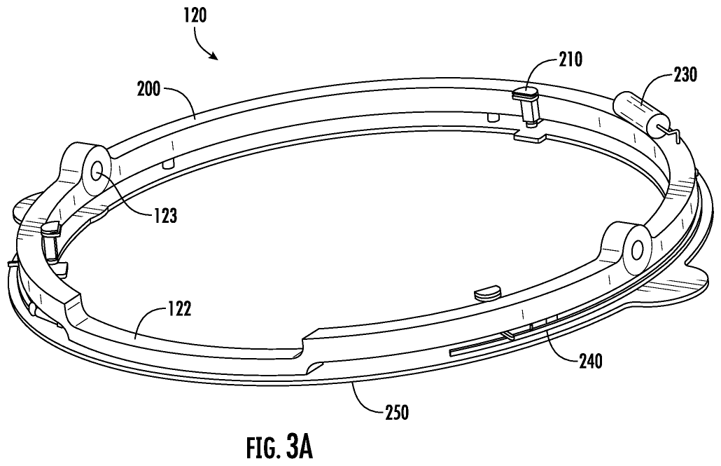

FIGS. 3A-3B show an enlarged view of the workpiece holder 120. FIG. 3A is a top view while FIG. 3B is the bottom view. In this disclosure, the bottom surface of the workpiece holder 120 is defined as the surface that faces toward the ion beam 360 during processing of the backside of the workpiece 300 while the top surface is the surface that the workpiece 300 is placed on.

Note that during processing, the top side of the workpiece holder 120 may be facing away from the ion beam 360, while the bottom side is facing the ion beam 360. The workpiece holder 120 includes a workpiece holder ring 200, which has an inner diameter that is slightly larger than the workpiece 300 that it is designed to support. The workpiece holder ring 200 may be constructed from aluminum or ceramic. In certain embodiments, polymers may be used. The workpiece holder ring 200 includes the two connection points 123, as described above. Additionally, the workpiece holder ring 200 includes a cutout 122 located along a front edge of the workpiece holder ring 200. The cutout 122 allows a robotic arm to place a workpiece on the workpiece holder 120 and then disengage from the workpiece support system. The width and height of the cutout 122 are selected to allow the robotic arm to pass through the space between the workpiece and the workpiece holder ring 200 without contacting these components. In another embodiment, the workpiece holder ring 200 is open at the front side rather than having a cutout 122.

The workpiece holder 120 also includes a plurality of workpiece clamps 210, which are described in more detail below. A clamp actuator 230 may also be disposed on the top surface of the workpiece holder ring 200. The clamp actuator 230 is in communication with a clamping linkage 240, as explained in more detail below.

As noted above, the bottom surface of the workpiece holder 120 faces the ion beam during processing. Therefore, a protective cover 250 may be disposed on the bottom surface of the workpiece holder 120. This protective cover 250 may be made from graphite or alumina. That protective cover 250 is removed in FIG. 3B to allow visibility to the components that are disposed between the protective cover 250 and the workpiece holder ring 200. However, the protective cover 250 may be seen in FIG. 2A.

FIG. 3B shows the clamping linkage 240 in more detail. The clamping linkage 240 is in communication with the clamp actuator 230. In this way, any movement of the clamp actuator 230 causes a corresponding rotation of the clamping linkage 240. The clamping linkage 240 is in contact with a plurality of levers 211, wherein each workpiece clamp 210 includes one lever 211. Rotation of the clamping linkage 240 causes each of the levers 211 to move between an open position to a closed position, as described in more detail below. In some embodiments, the clamping linkage 240 is in communication with a return spring 260. The return spring 260 biases the clamping linkage 240 toward one of the two positions, while the clamp actuator 230 is used to move the clamping linkage 240 to the other position. For example, the return spring 260 may bias the clamping linkage 240 to the closed position, such that a power failure does not cause the workpiece 300 to be released. Pegs 251 extend from the bottom surface of the workpiece holder ring 200 and are used to secure the protective cover 250 in place.

While FIG. 3B shows one clamp actuator 230 that controls all of the workpiece clamps 210, other embodiments are also possible. For example, a separate clamp actuator may be used for each workpiece clamp 210. Further, in certain embodiments, a separate return spring 260 may be associated with each workpiece clamp 210. Additionally, in some embodiments, the clamp actuator 230 may be disposed on the bottom surface of the workpiece holder ring 200.

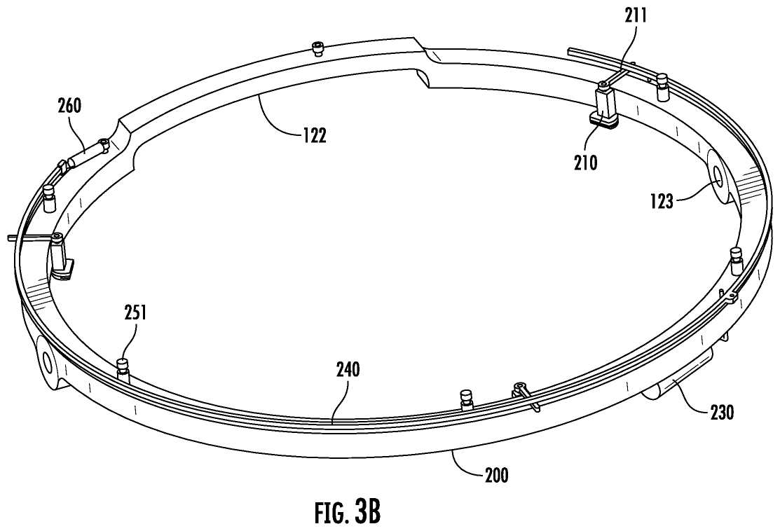

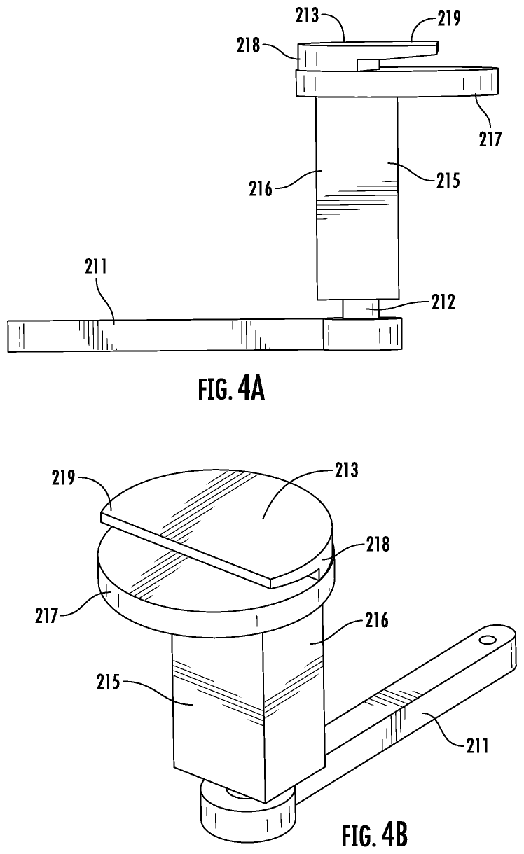

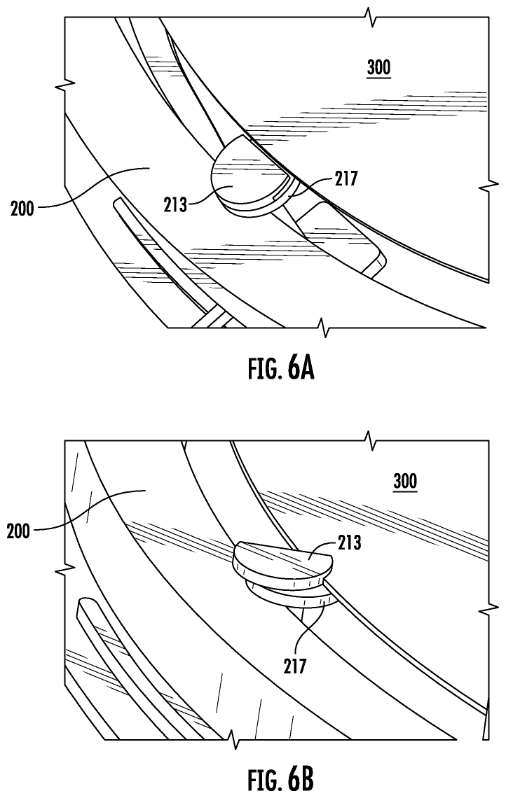

The workpiece clamps 210 are shown in FIGS. 4A-4B, 5A-5B and 6A-6B. FIG. 4A shows a sideview of the workpiece clamp 210 in the open position, while FIG. 4B shows a perspective view of the workpiece clamp 210 in the open position. The workpiece clamp 210 includes a seat 215 which is affixed to the inner wall of the workpiece holder ring 200. The seat 215 includes a body 216 and a top ledge 217. The top ledge 217 may extend outward beyond the body 216. When affixed to the workpiece holder ring 200, the top ledge 217 extends inward toward the center of the workpiece holder ring 200. The body 216 includes a hollow conduit extending therethrough. A shaft 212 is inserted through the hollow conduit. This shaft 212 is rotatable within the hollow conduit and is rigidly coupled to the lever 211 on the proximal end and rigidly attached to the pivotable latch 213 at the distal end. The pivotable latch 213 is disposed on top of the top ledge 217 and includes an indented portion 218 and an overhanging portion 219. The indented portion 218 has a height that is equal to or slightly greater than the thickness of the workpiece 300 to be clamped. The overhanging portion 219 extends farther inward than the indented portion 218. Note that the overhanging portion 219 does not extend inward as far as the top ledge 217 while in the open position. In this way, the workpiece rests only on the top ledge 217 when the workpiece clamps 210 are in the open position, as shown in FIG. 6A.

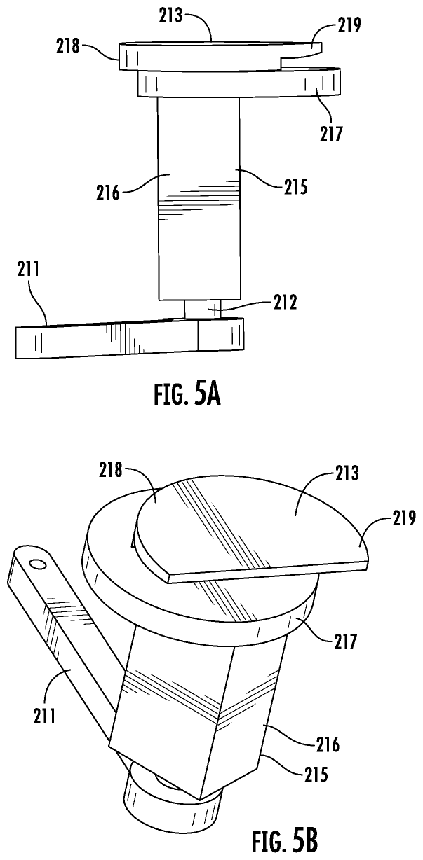

FIG. 5A shows a sideview of the workpiece clamp 210 in the closed or latched position, while FIG. 5B shows a perspective view of the workpiece clamp 210 in the latched position. In this position, the lever 211 is moved, causing the pivotable latch 213 to rotate relative to the seat 215. The overhanging portion 219 rotates so as to extend over the top ledge 217, locking the workpiece in place, as shown in FIG. 6B. When latched, the workpiece 300 is held between the top ledge 217 and the bottom surface of the overhanging portion 219. Further, the overhanging portion 219 is dimensioned such that, when in the latched position, the overhanging portion 219 extends only over the edge exclusion zone of the workpiece 300. In certain embodiments, the edge exclusion zone is a annular ring around the outer edge of the workpiece that has a width of 3 mm.

While FIGS. 4A-4B and 5A-5B show the seat 215 as being a separate component, it is understood that in some embodiments, the seat, which includes the body 216, the top ledge 217 and the hollow conduit, may be an integral part of the workpiece holder ring 200. Specifically, the seat 215 may be molded as part of the workpiece holder ring 200. Note that in this embodiment, the seat 215 is still affixed to the inner diameter of the workpiece holder ring 200.

A controller may be in communication with the twist motor 110, the tilt motor 140, and the clamp actuator 230 to control the operation of the workpiece support system. The controller includes a processing unit and an associated memory device. This memory device contains the instructions, which, when executed by the processing unit, enable the controller to perform the functions described herein. This memory device may be a non-volatile memory, such as a FLASH ROM, an electrically erasable ROM or other suitable devices. In other embodiments, the memory device may be a volatile memory, such as a RAM or DRAM. The processing unit may be a general purpose computer, a special purpose computer, a microcontroller or another type of electrical circuit.

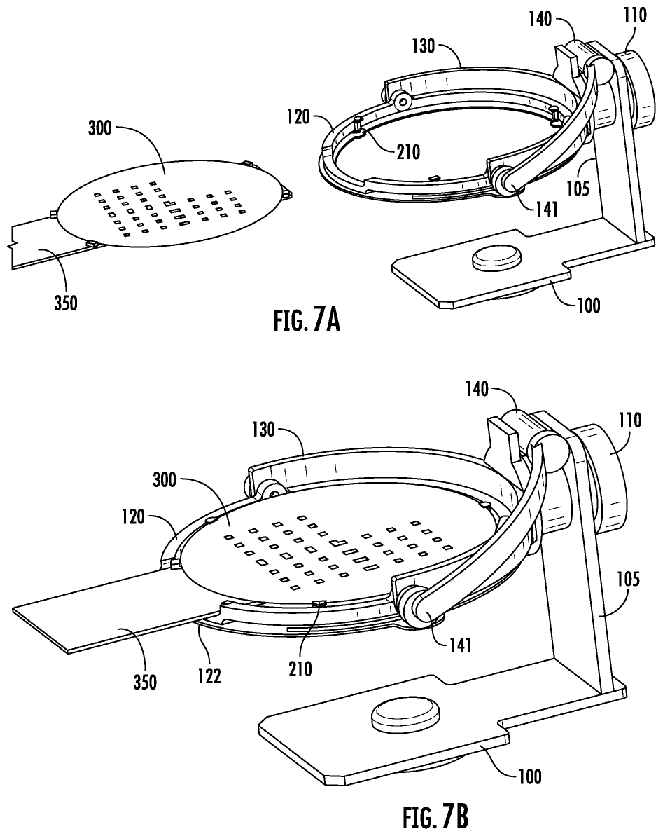

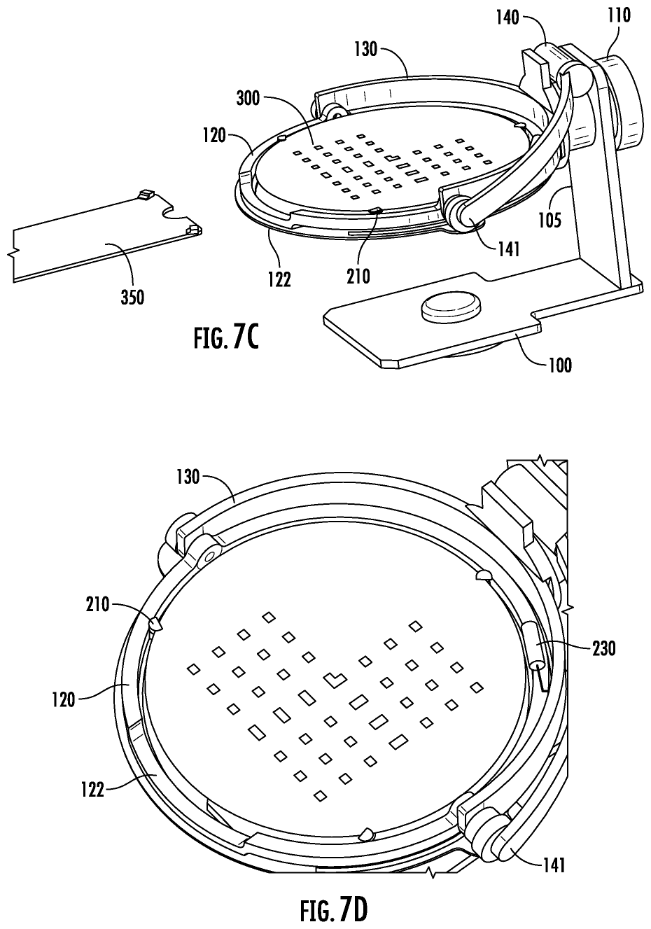

Having described all of the components of the workpiece support system, its operation will be described. First, as shown in FIG. 7A, a robotic arm 350 brings a workpiece 300 to the workpiece support system. The workpiece clamps 210 are in the open position. As shown in FIG. 7B, the robotic arm 350 is then lowered, causing the workpiece 300 to rest on the top ledges 217 of the seats 215, which support the workpiece 300 when the workpiece holder 120 is in the horizontal position. Note that the robotic arm 350 fits in the space defined by the cutout 122.

The robotic arm 350 lowers further so as to release the workpiece 300. At this point, the workpiece clamps 210 are in the open position, as shown in FIG. 6A. The robotic arm 350 then exits through the space defined by the cutout 122, as shown in FIG. 7C. The workpiece clamps 210 are then actuated to the latched position, which serves to hold the workpiece 300 in place, as shown in FIG. 6B. Note that the workpiece clamps 210 may be actuated before or after the robotic arm 350 is removed from the workpiece support system.

FIG. 7D shows a top view of the workpiece 300 clamped to the workpiece support system. Once the workpiece 300 is clamped, the tilt motor 140 may rotate the workpiece holder 120 so that the backside of the workpiece 300 faces the ion beam 360, as shown in FIGS. 2A-2B.

The ion beam 360 may be generated using an ion source. The ion source may be a indirectly heated cathode (IHC) ion source. Alternatively, the ion source may be a capacitively coupled plasma source, an inductively coupled plasma source, a Bernas source or another source. Thus, the type of ion source is not limited by this disclosure.

In one embodiment, the ion source may be disposed in a process chamber with the workpiece support system. Extraction electrodes may be used to extract ions from the ion source and direct them toward the workpiece. In another embodiment, the ion beam may be generated using a beam line ion implantation system. The ion implantation system may include an ion source, extraction optics to extract the ions from the ion source, and a mass analyzer to vary the path of the ions based on their charge and mass. Further, downstream from the mass analyzer may be a mass resolving aperture to selectively pass ions having a desired mass-to-charge ratio. Further downstream may be one or more additional components which serve to direct the ion beam 360 toward the workpiece 300. These components may include a collimator and/or an accelerator/deceleration stage. Of course, additional components may also be included in the beam line ion implantation system.

Note that while FIGS. 2A-2B show the backside of the workpiece 300 facing the ion beam, it is understood that the tilt motor 140 may be actuated in the opposite direction so that the front surface of the workpiece 300 is facing the ion beam 360. If the front surface of the workpiece 300 is to face the ion beam 360, a second protective cover may be disposed on the top surface of the workpiece holder ring 200. This second protective cover may be attached using pegs, similar to those used on the bottom surface.

As explained above, the workpiece 300 may be oriented in any twist angle or tilt angle using twist motor 110 and tilt motor 140, respectively. Additionally, the height and other tilt angle may be manipulated by movement of the rotatable shaft 101.

After processing, the workpiece 300 may be removed from the workpiece support system by performing this sequence in the opposite order.

The system and method described herein have many advantages. This workpiece support system allows processing of either side of the workpiece 300, without contacting the useable area on the workpiece. This allows the front surface of the workpiece to be processed, and then subsequent processing of the back surface without risking damage to the nanostructures formed on the front surface. Further, the two degree of freedom gimbal allows the workpiece support system to assume any orientation, allowing tilted implants, if desired.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited t thereto and that the present disclosure may be beneficially implemented in any number of environments for any number of purposes. Accordingly, the claims set forth below should be construed in view of the full breadth and spirit of the present disclosure as described herein.

What is claimed is:

1. A workpiece support system comprising:
a workpiece bracket, rotatably coupled to a support arm;
a workpiece holder rotatably mounted to the workpiece bracket;
wherein the workpiece holder comprises:
a workpiece holder ring; and
a plurality of workpiece clamps disposed along a diameter of the workpiece holder ring, the plurality of workpiece clamps each comprising a seat on which a bottom surface of a workpiece rests, and a pivotable latch, operable to clamp a front surface of the workpiece when in a closed position and unclamp the workpiece when in an open position.

2. The workpiece support system of claim 1, wherein the workpiece holder ring is rotatable about a tilt axis.

3. The workpiece support system of claim 2, wherein, when in the closed position, the workpiece clamps retain the workpiece when the workpiece holder is rotated at any tilt angle.

4. The workpiece support system of claim 1, wherein the workpiece bracket is rotatable about a twist axis.

5. The workpiece support system of claim 1, wherein, when in the closed position, the pivotable latch covers only an edge exclusion zone of the workpiece.

6. The workpiece support system of claim 1, wherein each of the plurality of workpiece clamps comprises:
the seat attached to an inner diameter of the workpiece holder ring, having a body and a top ledge, wherein the body has a hollow conduit passing therethrough, and the top ledge supports the bottom surface of the workpiece.

7. The workpiece support system of claim 6, wherein each of the plurality of workpiece clamps comprises a shaft passing through the hollow conduit, rigidly attached to the pivotable latch at a distal end and rigidly affixed to a lever at a proximal end.

8. The workpiece support system of claim 7, comprising a clamp actuator in communication with a clamping linkage, wherein each of the levers is attached to the clamping linkage, such that actuation of the clamp actuator causes all of the shafts to rotate between the open position and the closed position.

9. The workpiece support system of claim 8, further comprising a return spring, in communication with the clamping linkage, wherein the return spring biases the clamping linkage to either the open position or the closed position and actuation of the clamp actuator rotates the shafts to the other of the open position and the closed position.

10. The workpiece support system of claim 7, comprising a plurality of clamp actuators, each in communication with the lever of a respective workpiece clamp, such that actuation of the plurality of clamp actuators causes all of the shafts to rotate between the open position and the closed position.

11. The workpiece support system of claim 10, further comprising a plurality of return springs, each in communication with the lever of a respective workpiece clamp, wherein the return spring biases the lever to either the open position or the closed position and actuation of a respective clamp actuator rotates the shaft to the other of the open position and the closed position.

12. The workpiece support system of claim 1, wherein the workpiece holder ring comprises a cutout along a portion of a front surface to allow insertion and removal of a robotic arm.

13. A workpiece support system comprising:
a workpiece bracket;
a workpiece holder rotatably mounted to the workpiece bracket;
wherein the workpiece holder comprises:
a workpiece holder ring; and
a plurality of workpiece clamps disposed along a diameter of the workpiece holder ring; the plurality of workpiece clamps each comprising:
a seat attached to an inner diameter of the workpiece holder ring, having a body and a top ledge, wherein the body has a hollow conduit passing therethrough, and the top ledge supports a bottom surface of a workpiece; and
a shaft passing through the hollow conduit, rigidly attached to a pivotable latch at a distal end and rigidly affixed to a lever at a proximal end.

14. The workpiece support system of claim 13, wherein, when in a closed position, the pivotable latch covers only an edge exclusion zone of the workpiece.

15. The workpiece support system of claim 13, comprising a clamp actuator in communication with a clamping linkage, wherein each of the levers is attached to the clamping linkage, such that actuation of the clamp actuator causes all of the shafts to rotate between an open position and a closed position.

16. The workpiece support system of claim 15, further comprising a return spring, in communication with the clamping linkage, wherein the return spring biases the clamping linkage to either the open position or the closed position and actuation of the clamp actuator rotates the shafts to the other of the open position and the closed position.

17. The workpiece support system of claim 15, further comprising a protective cover, such that the clamping linkage is disposed between the protective cover and an underside of the workpiece holder ring.

18. The workpiece support system of claim 13, wherein the workpiece bracket and the workpiece holder form a gimbal having two degrees of rotational freedom.

19. The workpiece support system of claim 13, comprising a plurality of clamp actuators, each in communication with the lever of a respective workpiece clamp, such that actuation of the plurality of clamp actuators causes all of the shafts to rotate between an open position and a closed position.

20. The workpiece support system of claim 19, further comprising a plurality of return springs, each in communication with the lever of a respective workpiece clamp, wherein the return spring biases the lever to either the open position or the closed position and actuation of a respective clamp actuator rotates the shaft to the other of the open position and the closed position.
